(19) United States
(12) Patent Application Publication
(10) Pub. No.: US 2009/0310298 A1
(43) Pub. Date: Dec. 17, 2009

(54) BIAXIAL MODULE AND PORTABLE ELECTRONIC APPARATUS WITH BIAXIAL MODULE

(76) Inventors: Mei-Fang Chou, Taipei (TW); Pao-Tung Weng, Taipei (TW); Chih-Ho Hsieh, Taipei (TW)

Correspondence Address: Muncy, Geissler, Olds & Lowe, PLLC, P.O. BOX 1364, FAIRFAX, VA, 22038-1364, US

(21) Appl. No.: 12/435,436

(22) Filed: May 5, 2009

(30) Foreign Application Priority Data
Jun. 16, 2008 (TW) 097122408

(51) Int. Cl. H05K 5/00; E05D 5/10; E05D 11/10

(52) U.S. Cl. 361/679.55; 16/386; 16/343

(57) ABSTRACT

A portable electronic apparatus with a biaxial module includes a first main body, a second main body, and a biaxial module connected with the first and second main bodies. The biaxial module includes a first axial unit, a second axial unit, and a connecting unit. The first axial unit includes a first axial part and a first connecting part pivoted on the first axial part. The second axial unit includes a second axial part and a second connecting part connected with the second axial part. The connecting unit is connected with the first axial unit and the second axial unit and pivoted on the second axial part.

### CROSS REFERENCE TO RELATED APPLICATIONS

This Non-provisional application claims priority under 35 U.S.C. §119(a) on Patent Application No(s). 097122408 filed in Taiwan, Republic of China on Jun. 16, 2008, the entire contents of which are hereby incorporated by reference.

### BACKGROUND OF THE INVENTION

1. Field of Invention

The invention relates to a portable electronic apparatus and, more particularly, to a portable electronic apparatus and a biaxial module thereof.

2. Related Art

There are various kinds of portable electronic apparatus such as a notebook computer, an ultra mobile personal computer, or a mobile communication apparatus. Generally, a portable electronic apparatus includes a pivot module to be folded conveniently. However, a conventional pivot module generally is a single axis module, and therefore the rotation angle is limited and then the usability of the portable electronic apparatus is restricted.

### SUMMARY OF THE INVENTION

According to the invention, a biaxial module includes a first axial unit, a second axial unit, and a connecting unit. The first axial unit includes a first axial part and a first connecting part pivoted on the first axial part. The second axial unit includes a second axial part and a second connecting part connected with the second axial part. The connecting unit is connected with the first axial unit and the second axial unit and pivoted on the second axial part.

According to the invention, a portable electronic apparatus includes a first main body, a second main body, and a biaxial module. The biaxial module is connected with the first and second main bodies, and it includes a first axial unit, a second axial unit, and a connecting unit. The first axial unit includes a first axial part and a first connecting part, and the first connecting part is pivoted on the first axial part and connected with the first main body. The second axial unit includes a second axial part and a second connecting part, and the second axial part is connected with the second connecting part while the second connecting part is connected with the second main body. The connecting unit is connected with the first axial unit and the second axial unit and pivoted on the second axial part.

As stated above, a portable electronic apparatus with a biaxial module includes a first axial unit and a second axial unit. The first connecting part of the first axial unit may rotate around the first axial part, and the first axial unit and the connecting unit may rotate around the second axial part of the second axial unit, so that a biaxial rotation is formed. Therefore, the foldable angle scope of the portable electronic apparatus is broadened to enhance the usability of the portable electronic apparatus.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing a biaxial module according to a preferred embodiment of the invention;

FIG. 2A to FIG. 2E are schematic diagrams showing a biaxial module during operating according to a preferred embodiment of the invention; and

FIG. 3 is a schematic diagram showing a portable electronic apparatus according to a preferred embodiment of the invention.

### DETAILED DESCRIPTION OF THE INVENTION

Hereinafter, according to a preferred embodiment of the invention, a portable electronic apparatus and a biaxial module will be described with reference to the accompanying drawings. The same reference numbers will be used to refer to the same parts.

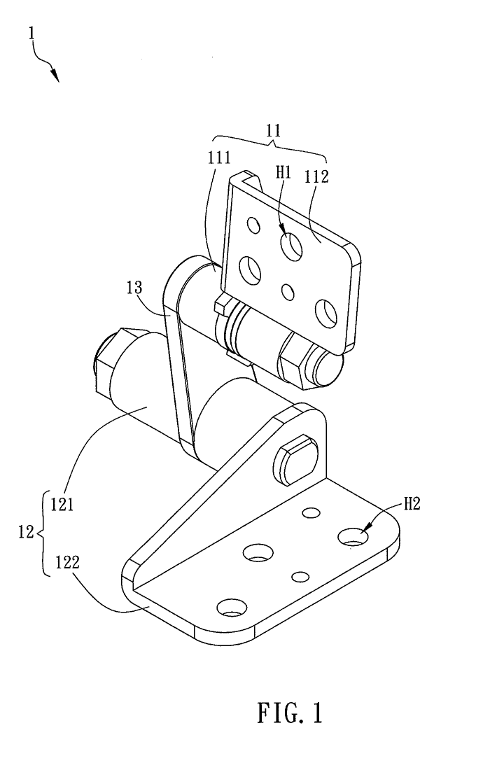

As shown in FIG. 1, according to a preferred embodiment, a biaxial module includes a first axial unit 11, a second axial unit 12, and a connecting unit 13.

The first axial unit 11 includes a first axial part 111 and a first connecting part 112. The first connecting part 112 is pivoted on the first axial part 111 and may rotate around the first axial part 111. In the embodiment, the first connecting part 112 has a plurality of assembling holes H1 to be locked to external members. Herein, a locking mode is just taken as an example, and the first connecting part 112 may be connected with the external members in other connecting modes, such as a mode of fastening, adhering, embedding, sleeving, or welding.

The second axial unit 12 includes a second axial part 121 and a second connecting part 122, and the second axial part 121 is connected with the second connecting part 122. In the embodiment, the second axial part 121 and the second connecting part 122 are fastened with each other. Herein, a locking mode is taken for example. The second connecting part 122 may have a plurality of assembling holes H2 to be locked to external members. Herein, a locking mode is taken for example, and the second connecting part 122 also may be connected with external members in other connecting modes, such as a mode of fastening, adhering, embedding, sleeving, or welding.

The connecting unit 13 is connected with the first axial unit 11 and the second axial unit 12, and it is pivoted on the second axial part 121. In the embodiment, the connecting unit 13 is, for example, a sheet metal, and it has two punch holes (not shown). The first axial part 111 and the second axial part 121 are disposed through the connecting unit 13 via the two punch holes, respectively. The connecting unit 13 may be connected with the first axial unit 11 and the second axial unit 12 in other connecting modes, such as a mode of fastening, adhering, embedding, or welding etc.

In addition, the connecting unit 13 is pivoted on the second axial part 121 and may rotate around the second axial part 121. The connecting unit 13 may rotate to make the first axial unit 11 rotate around the second axial part 121. The connecting part 112 may rotate round the first axial part 111, and the first axial unit 11 and the connecting unit 13 may rotate around the second axial part 121, so that a biaxial rotation is formed.

In addition, in the embodiment, the torque force of the first axial unit 11 is less than that of the second axial unit 12. In actual operation, a user applies force to the first connecting part 112 or external members thereon to make first connecting part 112 rotate around the first axial part 111. Since the torque force of the first axial unit 11 is less than that of the second axial unit 12, the connecting unit 13 and the second axial unit 12 are stationary relative to each other during the rotation.

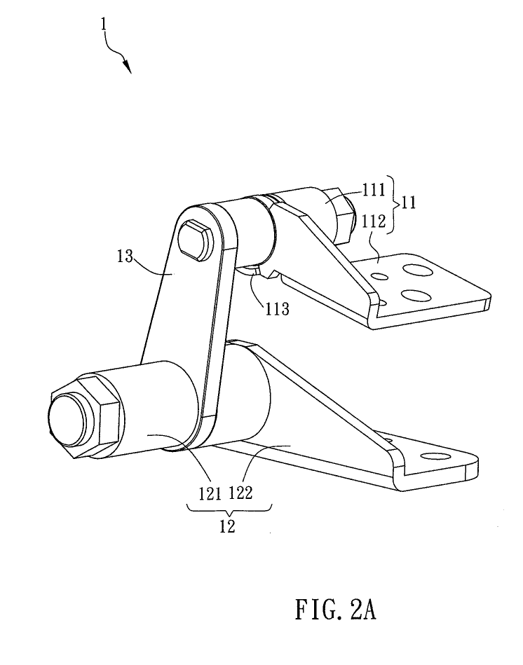

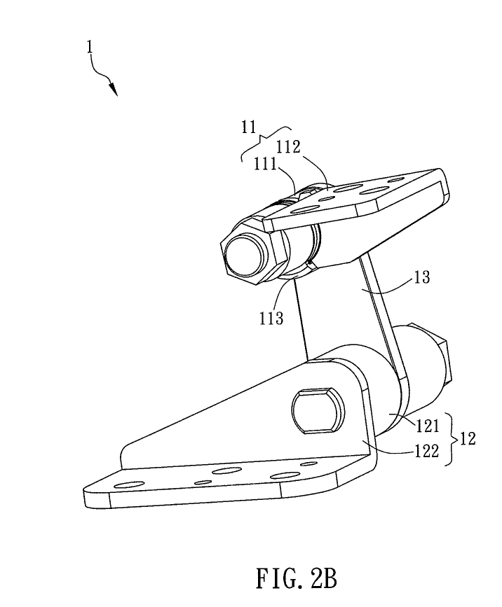

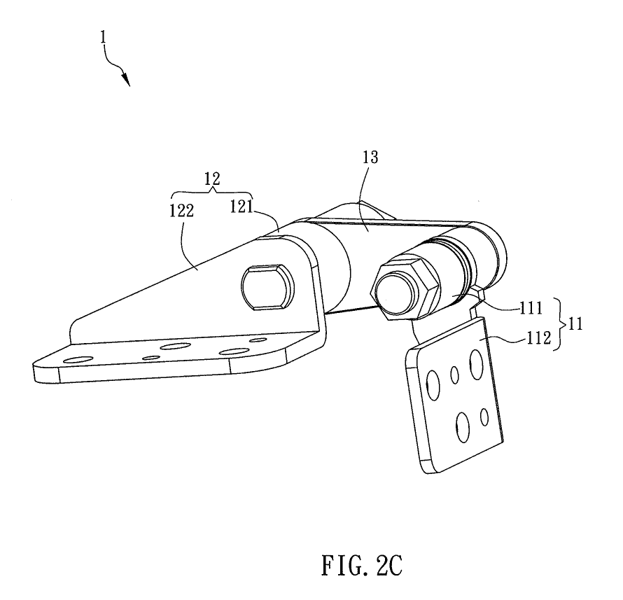

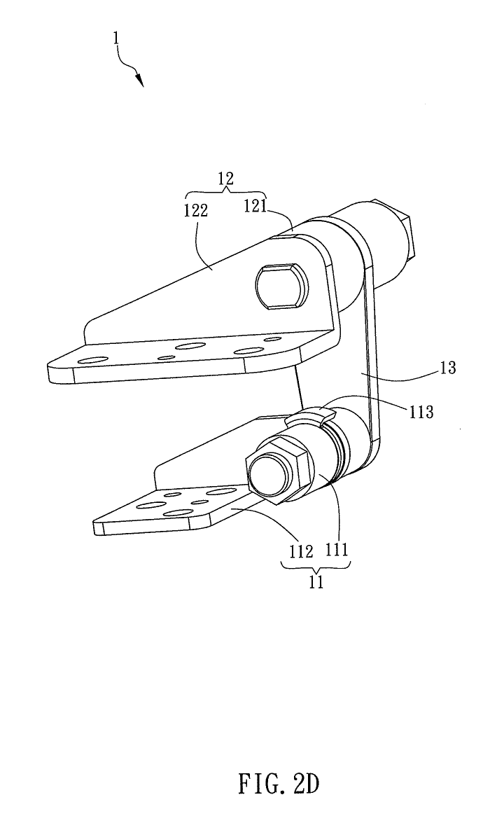

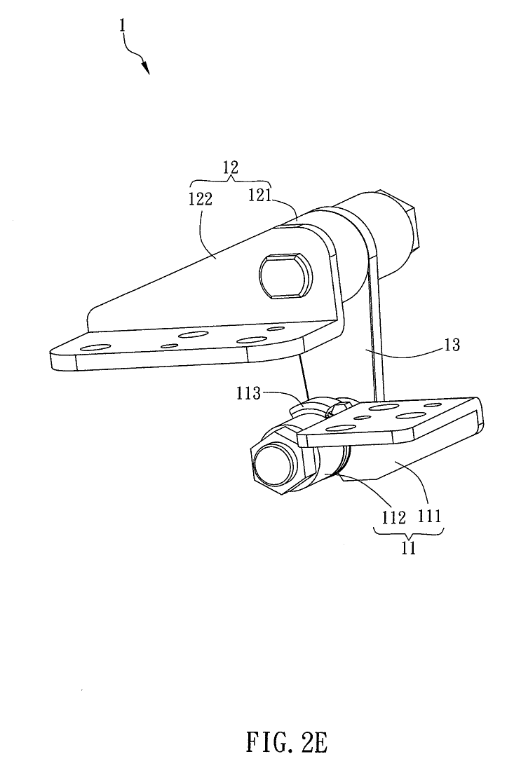

Hereinafter, as shown in FIG. 2A to FIG. 2D, rotation situations of the biaxial module 1 are described.

FIG. 2A shows the biaxial module 1 in initial status that the first connecting part 112 is at a zero angle. In the embodiment, the first axial unit 11 further includes a stopper 113. The stopper 113 is connected with the first axial part 111 and adjacent to the first connecting part 112 to limit the rotating angle of the first connecting part 112. Herein, the stopper 113 may restrict the first connecting part 112 at a zero angle defined in the embodiment. The stopper 113 may be connected with the first axial part 111 in a fastening, adhering, embedding, sleeving, locking, or integrating mode. In the embodiment, the stopper 113 is embedded and sleeved on the first axial part 111. In addition, the shape of the stopper 113 is not limited in the embodiment. For example, it may be a shape of ring, arc, plate, block, or concavo-convex part, which depends on actual requirements.

FIG. 2B shows the first connecting part 112 rotates to a first angle such as 180 degrees from the zero angle. When a user applies force to the first connecting part 112 or external members thereon to make the first connecting part 112 rotate around the first axial part 111, since the force of the first axial unit 11 is less than that of the second axial unit 12, the connecting unit 13 and the second axial unit 12 are stationary relative to each other during rotating. In the embodiment, the stopper 113 may restrict the rotation the first connecting part 112 to the first angle.

FIG. 2C shows the first connecting part 112 rotates to a second angle such as 270 degrees from the first angle. Since the stopper 113 restricts the first connecting part 112 at the first angle to disable the first connecting part 112 to rotate around the first axial part 111, the first connecting part 112 may rotate from the first angle to the second angle due to the rotation of the connecting unit 13 around the second axial part 121. Therefore, the first connecting part 112 and the first axial part 111 are stationary relative to each other during the rotation from the first angle to the second angle.

FIG. 2D shows the first connecting part 112 rotates to a third angle such as 360 degrees from the second angle. During the rotation, the connecting unit 13 goes on rotating around the second axial part 121 to drive the first connecting part 112 to rotate form the second angle to the third angle.

The process of rotating the first connecting part 112 from the third angle to the zero angle is described hereinbelow. FIG. 2D and FIG. 2E show that the first connecting part 112 rotates from the third angle to the first angle via the second angle. During the process, since the force of the first axial unit 11 is less than that of the second axial unit 12, the connecting unit 13 does not rotate, while the first connecting part 112 rotates around the first axial part 111 from the third angle to the first angle via the second angle. In addition, the first connecting part 112 is restricted at the first angle by the stopper 113 and cannot rotate forwards.

FIG. 2E and FIG. 2A show that the first connecting part 112 rotates from the first angle to the zero angle. During the process, the connecting unit 13 rotates with the first axial unit 11 around the second axial part 121 to make the first connecting part 112 rotate from the first angle to the zero angle. The first connecting part 112 and the first axial part 111 are stationary relative to each other during the process.

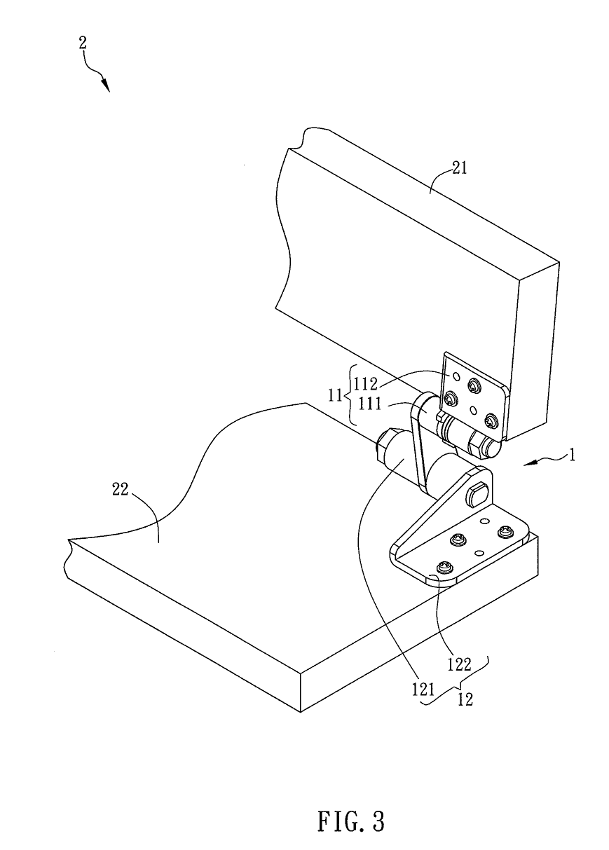

As shown in FIG. 3, the portable electronic apparatus 2 according to a preferred embodiment of the invention includes a first main body 21, a second main body 22, and a biaxial module 1. In the embodiment, the portable electronic apparatus 2 may be a notebook computer, an ultra mobile personal computer, or a mobile communication apparatus. The first main body 21 and the second main body 22 are two parts of the portable electronic apparatus 2. For example, the first main body 21 may be a display module (such as a LCD module) of the potable electronic apparatus 2, while the second main body 22 may be an operating module (which may include a keyboard) of the potable electronic apparatus 2.

Since the biaxial module 1 has been illustrated in detail above, herein it is not illustrated for concise purpose. In the embodiment, the first connecting part 112 of the biaxial module 1 is connected with the first main body 21, while the second connecting part 122 is connected with the second main body 22. The connection mode of the first main body 21, the second main body 22 and the biaxial module 1 may be a mode of locking, fastening, adhering, embedding, sleeving, or welding, and herein the locking mode is taken for example.

In the embodiment, when the biaxial module 1 is operated, the first connecting part 112 rotates with the first main body 21 around the first axial part 111 and the second axial part 121, and the second connecting part 122 and the second main body 22 are fastened with each other to allow the first main body 21 to rotate relative to the second main body 22. Since the operation of biaxial module 1 has been illustrated in detail above, herein it is not illustrated for concise purpose.

As stated above, a portable electronic and a biaxial module include a first axial unit and a second axial unit. The first connecting part of the first axial unit may rotate around the first axial part, and the first axial unit and the connecting unit may rotate around the second axial part of the second axial unit to form a biaxial rotation. Therefore, the foldable angle scope of the portable electronic apparatus is broadened to enhance the usability of the portable electronic apparatus.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A biaxial module, comprising:
a first axial unit having a first axial part and a first connecting part pivoted on the first axial part;
a second axial unit having a second axial part and a second connecting part connected with the second axial part; and
a connecting unit connected with the first axial unit and the second axial unit and pivoted on the second axial part.

2. The biaxial module according to claim 1, wherein the first axial unit further comprises a stopper connected with the first axial part and adjacent to the first connecting part to limit a rotating angle of the first connecting part.

3. The biaxial module according to claim 2, wherein the stopper is connected with the first axial part in a fastening, embedding, adhering, sleeving, locking, or integrating mode.

4. The biaxial module according to claim 2, wherein the stopper is in a shape of ring, arc, plate, lump, or concavo-convex.

5. The biaxial module according to claim 1, wherein the first axial part and the second axial part are disposed through the connecting unit.

6. The biaxial module according to claim 1, wherein the torque force of the first axial unit is less than that of the second axial unit.

7. A portable electronic apparatus with a biaxial module, comprising:
a first main body;
a second main body; and
a biaxial module connected with the first main body and the second main body and further including:
a first axial unit having a first axial part and a first connecting part, wherein the first connecting part is pivoted on the first axial part and connected with the first main body;
a second axial unit having a second axial part and a second connecting part, wherein the second connecting part is connected to the second axial part and the second main body; and
a connecting unit connected with the first axial unit and the second axial unit and pivoted on the second axial part.

8. The portable electronic apparatus according to claim 7, wherein the first axial unit further comprises a stopper connected with the first axial part and adjacent to the first connecting part to limit a rotating angle of the first connecting part.

9. The portable electronic apparatus according to claim 8, wherein the stopper is connected with the first axial part in a fastening, embedding, adhering, sleeving, locking, or integrating mode.

10. The portable electronic apparatus according to claim 8, wherein the stopper is in a shape of ring, arc, plate, lump, or concavo-convex.

11. The portable electronic apparatus according to claim 7, wherein the first axial part and the second axial part are disposed through the connecting unit, respectively.

12. The portable electronic apparatus according to claim 7, wherein the torque force of the first axial unit is less than that of the second axial unit.

13. The portable electronic apparatus according to claim 7, wherein the portable electronic apparatus is a notebook computer, an ultra mobile personal computer, or a mobile communication apparatus.
